(19) United States
(12) Patent Application Publication
(10) Pub. No.: US 2010/0167489 A1
(43) Pub. Date: Jul. 1, 2010

(54) MIM CAPACITOR AND METHOD OF FABRICATING THE SAME

(76) Inventor: Seok-Joon Oh, Jeonju-si (KR)

Correspondence Address: SHERR & VAUGHN, PLLC, 620 HERNDON PARKWAY, SUITE 320, HERNDON, VA, 20170, US

(21) Appl. No.: 12/492,169

(22) Filed: Jun. 26, 2009

(30) Foreign Application Priority Data
Jun. 26, 2008 (KR) 10-2008-0061024

(51) Int. Cl. H01L 21/02

(52) U.S. Cl. 438/393; 257/E21.008

(57) ABSTRACT

A method of fabricating an MIM capacitor may include a first electrode formed on and/or over a semiconductor substrate, a dielectric layer composed of an oxygen material formed on and/or over the first electrode under an oxygen atmosphere. A second electrode is formed on and/or over the dielectric layer. Because the dielectric layer is formed under an oxygen atmosphere, an oxygen composition ratio of the dielectric layer is increased.

The present application claims priority under 35 U.S.C. §119 to Korean Patent Application No. 10-2008-0061024, filed on Jun. 26, 2008, which is hereby incorporated by reference in its entirety.

### BACKGROUND

A logic circuit demanding a high-speed operation among semiconductor devices may require a high-capacity capacitor and enhancement of the dielectric layer, thereby adding complexity to the manufacturing process of the capacitor.

### SUMMARY

Embodiments relate to a method of fabricating a metal-insulator-metal (MIM) capacitor that enhances characteristics of a dielectric layer by increasing a composition ratio of oxygen in the dielectric layer.

In accordance with embodiments, a method of fabricating a MIM capacitor may include at least one of the following: forming a first electrode on and/or over a semiconductor substrate; and then forming a dielectric layer on and/or over the first electrode under an oxygen atmosphere; and then forming a second electrode on and/or over the dielectric layer.

In accordance with embodiments, a method of fabricating a semiconductor device may include at least one of the following: forming a first electrode on and/or over a semiconductor substrate; and then forming a dielectric layer composed of an oxide material on and/or over the first electrode under an oxygen atmosphere; and then faulting a second electrode on and/or over the dielectric layer.

In accordance with embodiments, an MIM capacitor device may include at least one of the following: a semiconductor substrate; a first electrode disposed on and/or over the semiconductor substrate and including titanium nitride (TiN); a dielectric layer disposed on and/or over the first electrode and including strontium titanate (SrTiO₃); and a second electrode disposed on and/or over the dielectric layer.

In accordance with embodiments, a method may include at least one of the following: forming a lower electrode comprising a first metal layer over and contacting a semiconductor substrate; and then performing a thermal treatment on the semiconductor substrate including the lower electrode after forming the lower electrode; and then forming a doped oxide layer over and contacting the first metal layer after performing the thermal treatment; and then forming a plurality of upper electrode comprising a second metal layer over and contacting the doped oxide layer. In accordance with embodiments, the doped oxide layer is formed in an oxygen atmosphere.

A method of fabricating an MIM capacitor in accordance with embodiments serves to prevent reduction in an oxygen composition ratio of a dielectric layer due to formation of the dielectric layer under an oxygen atmosphere. This may also serve to provide an MIM capacitor with an improved characteristic of a dielectric layer.

### DRAWINGS

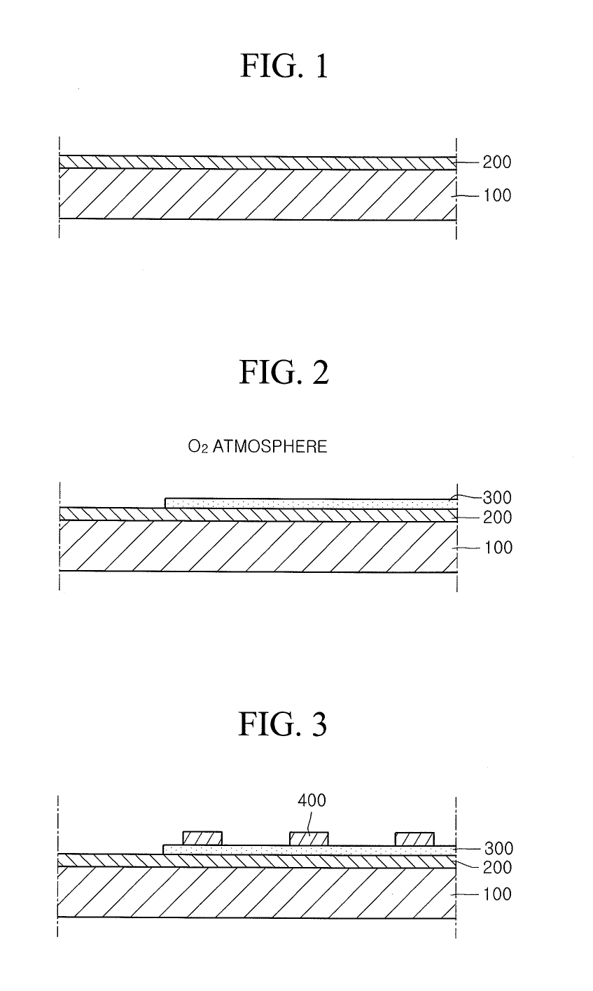

Example FIGS. 1 to 3 illustrate a method of fabricating an MIM capacitor in accordance with embodiments.

### DESCRIPTION

During description of embodiments, when each substrate, film, pattern, layer, region, or electrode is formed “on” or “under” a substrate, film, pattern, layer, region, or electrode, it can be directly formed “on” or “under” another film, pattern, layer, region, or electrode, or can be indirectly formed, that is, one or more intervening substrates, films, patterns, layers, regions, or electrodes may also be present. Additionally, a base level for the “on” or “under” of each components is described with reference to the drawings. A dimension of each component in the drawings may be exaggerated for description, and does not mean its actual dimension.

As illustrated in example FIG. 1, a lower or first electrode 200 is formed on and/or over a semiconductor substrate 100. First electrode 200 may be formed to directly contact semiconductor substrate 100. First electrode 200 may be composed of a material that includes titanium nitride (TiN). First electrode 200 may be formed using a pulsed laser deposition (PLD) process. For example, semiconductor substrate 100 and a TiN target are disposed inside a chamber. A laser is then projected on the TiN target. TiN is then separated from the TiN target and then deposited on and/or over semiconductor substrate 100 to thereby form first electrode 200. The laser may be a KrF eximer laser (λ=248 nm). After forming first electrode 200, semiconductor substrate 100 including first electrode 200 may then be thermally treated at a temperature range of between approximately 700° C. to 900° C. in a vacuum state in a range between approximately 6 to 10 Torr.

As illustrated in example FIG. 2, after conducting the thermal treatment process, dielectric layer 300 may then be formed on and/or over first electrode 200 under an oxygen (O₂) atmosphere. Dielectric layer 300 may be formed to directly contact first electrode 200. Dielectric layer 300 may be formed to directly contact first electrode 200 at an uppermost surface of first electrode 200. Dielectric layer 300 may be formed of an oxide material such as an oxide of at least one of strontium (Sr), titanium (Ti), lanthanum (La), manganese (Mn) and promethium (Pm). Dielectric layer 300 may be formed of an oxide material such as an oxide of a compound that includes Sr and Ti, or an oxide of a compound that includes La and Mn, or an oxide of a compound that includes Pm and Mn. Dielectric layer 300 may be formed of only an oxide. Additionally, dielectric layer 300 may be formed of only an oxide doped with at least one of Niobium (Nb), potassium (K) and chromium (Cr). For instance, dielectric layer 300 may include Nb-doped strontium titanate (SrTiO₃). Dielectric layer 300 may be formed using the PLD process. Dielectric layer 300 may be formed of at least one of Ca-doped LaMnO₃, Ca-doped PrMnO₃ (PCMO), and Cr-doped SrTiO₃.

Dielectric layer 300 may be formed using the following processes. Before forming dielectric layer 300, semiconductor substrate 100 may be thermally treated for approximately 1 to 2 min at a temperate range of between approximately 700° C. to 900° C. under an oxygen (O₂) atmosphere where a partial pressure of oxygen is in a range of between approximately 5 to 10 Torr or approximately 3 to 10 Torr. Next, a doped-oxide target such as Nb-doped SrTiO₃ and semiconductor substrate 100 are then disposed in a chamber. A laser such as a KrF excimer laser (λ=248 nm) may then be projected on the Nb-doped SrTiO₃ target at a temperate range of between approximately 700° C. to 900° C. under an oxygen atmosphere where a partial pressure of oxygen is in a range of between approximately 5 to 10 Torr or approximately 3 to 10 Torr. Dielectric layer 300 composed of Nb-doped SrTiO₃ is thereby formed on and/or over first electrode 200. Again, one of a Ca-doped LaMnO₃, Ca-doped PrMnO₃ (PCMO), or Cr-doped SrTiO₃ target, instead of the Nb-doped SrTiO₃ target, may be used in the PLD process.

Semiconductor substrate 100 may then be thermally treated at a temperate range of between approximately 700° C. to 900° C. under an oxygen atmosphere where a partial pressure of oxygen is in a range of between approximately 5 to 10 Torr or approximately 3 to 10 Torr. Later, semiconductor substrate 100 may be thermally treated at a temperate range of between approximately 700° C. to 900° C. under a vacuum state of approximately 6 to 10 Torr.

As illustrated in example FIG. 3, a plurality of upper or second electrodes 400 may then be formed on and/or over the dielectric layer 300 through a PLD process. Second electrode 400 may be formed to directly contact dielectric layer 300. Second electrode 400 may be formed to directly contact dielectric layer 300 at an uppermost surface of dielectric layer 300. Second electrode 400 may be spaced apart on dielectric layer 300. Second electrode 400 may be composed of a material that includes TiN. Second electrode 400 may be formed using a shadow mask. For example, semiconductor substrate 100 and a TiN target may be disposed in a chamber, and the shadow mask is disposed on and/or over dielectric layer 300. A laser such as a KrF excimer laser (λ=248 nm) may then be projected on the TiN target. TiN is then separated from the TiN target and then deposited on and/or over semiconductor substrate 100, thereby forming second electrode 400 composed of TiN and completing the MIM capacitor.

A MIM capacitor which may include a TiN—SrTiO₃—TiN structure is formed using the above processes. Since dielectric layer 300 is formed under an oxygen atmosphere, it has a higher oxygen composition ratio than dielectric layers formed under other types of gas atmospheres. For example, if a composition of a dielectric layer formed using the PLD process under a non-oxygen gas atmosphere or under a vacuum state is analyzed, it may be SrTiO_{2.5}. This is because an oxygen atom in the SrTiO₃ target is decomposed by the laser. Therefore, it remains in an oxygen gas state in the chamber. Accordingly, when a dielectric layer is formed under a non-oxygen gas atmosphere or a vacuum state, an oxygen composition ratio becomes lowered, such that a crystal structure of a dielectric layer may vary. Additionally, characteristics of a dielectric layer are deteriorated.

On the other hand, in the manufacturing method of the MIM capacitor in accordance with embodiments, since the dielectric layer is formed under an oxygen atmosphere, even when an oxygen atom in the SrTiO₃ target changes into a gas state, oxygen still can be provided because of the presence of oxygen in the chamber. Accordingly, the manufacturing method of the MIM capacitor in accordance with embodiments can prevent an oxygen composition ratio of the dielectric layer from being reduced and therefore, the dielectric layer can have an enhanced crystal structure. Meaning, in accordance with embodiments, the manufacturing method of the MIM capacitor forms a dielectric layer having the same composition ratio as the target on a lower or first electrode 200 during the PLD process.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a first electrode over a semiconductor substrate; and then
forming a dielectric layer over the first electrode under an oxygen atmosphere; and then
forming a plurality of second electrodes over the dielectric layer.

2. The method of claim 1, wherein the dielectric layer comprises SrTiO₃.

3. The method of claim 1, wherein forming the dielectric layer comprises:
providing a Nb-doped SrTiO₃ target and the semiconductor substrate including the first electrode in a chamber;
projecting a laser on the Nb-doped SrTiO₃ target under an oxygen atmosphere.

4. The method of claim 1, wherein the first electrode and the second electrodes each comprise TiN.

5. The method of claim 1, wherein forming the dielectric layer comprises:
annealing the semiconductor substrate including the first electrode under an oxygen atmosphere; and then
depositing a doped metal layer composed of Nb-doped SrTiO₃ over the first electrode under an oxygen atmosphere; and then
annealing the semiconductor substrate including the first electrode and the doped metal layer composed of Nb-doped SrTiO₃ under an oxygen atmosphere.

6. The method of claim 1, wherein the dielectric layer comprises an oxide of a compound comprising Sr and Ti.

7. A method comprising:
forming a first metal layer as a first electrode over and contacting a semiconductor substrate; and then
forming an oxide layer under an oxygen atmosphere as a dielectric layer over and contacting the first electrode; and then
forming a second metal layer as a second electrode over and contacting the dielectric layer.

8. The method of claim 7, wherein the first electrode and the second electrode each comprise TiN.

9. The method of claim 7, wherein the oxide layer comprises an oxide of at least one of a compound that includes Sr and Ti, a compound that includes La and Mn and a compound that includes Pm and Mn.

10. The method of claim 9, wherein the oxide layer is a doped oxide layer.

11. The method of claim 10, wherein the doped oxide layer is doped with at least one of Nb, K and Cr.

10. The method of claim 7, wherein the oxide layer is a doped oxide layer.

11. The method of claim 10, wherein the doped oxide layer is doped with at least one of Nb, K and Cr.

12. A method comprising:
forming a lower electrode comprising a first metal layer over and contacting a semiconductor substrate; and then
performing a thermal treatment on the semiconductor substrate including the lower electrode after forming the lower electrode; and then
forming a doped oxide layer over and contacting the first metal layer after performing the thermal treatment; and then
forming a plurality of upper electrodes comprising a second metal layer over and contacting the doped oxide layer,
wherein the doped oxide layer is formed in an oxygen atmosphere.

13. The method of claim 12, wherein the first metal layer and the second metal layer comprises titanium nitride (TiN).

14. The method of claim 13, wherein the doped oxide layer comprises an oxide material of at least one of strontium (Sr), titanium (Ti), lanthanum (La), manganese (Mn) and promethium (Pm).

15. The method of claim 14, wherein the doped oxide layer is doped with at least one of Niobium (Nb), potassium (K) and chromium (Cr).

16. The method of claim 12, wherein the doped oxide layer comprises an oxide material of at least one of strontium (Sr), titanium (Ti), lanthanum (La), manganese (Mn) and promethium (Pm).

17. The method of claim 16, wherein the doped oxide layer is doped with at least one of Niobium (Nb), potassium (K) and chromium (Cr).

18. The method of claim 12, wherein the doped oxide layer is doped with at least one of Niobium (Nb), potassium (K) and chromium (Cr).

19. The method of claim 12, wherein the doped oxide layer comprises an oxide of at least one of a compound that includes Sr and Ti, a compound that includes La and Mn and a compound that includes Pm and Mn.

20. The method of claim 12, wherein the doped oxide layer comprises at least one of Nb-doped SrTiO₃, Ca-doped LaMnO₃, Ca-doped PrMnO₃ (PCMO), and Cr-doped SrTiO₃.
